(19) United States
(12) Patent Application Publication
(10) Pub. No.: US 2026/0237418 A1
(43) Pub. Date: Aug. 13, 2026

(54) PROCESSING-IN-MEMORY (PIM) OPERATION AWARE REFRESH SCHEDULING

(71) Applicant: QUALCOMM Incorporated, San Diego, CA (US)

(72) Inventors: Pan Deng, San Diego, CA (US); Subbarao Palacharla, San Diego, CA (US); Rui Cao, San Diego, CA (US); Pankaj Deshmukh, San Diego, CA (US); Jungwon Suh, San Diego, CA (US)

(21) Appl. No.: 19/052,751

(22) Filed: Feb. 13, 2025

(51) Int. Cl. G11C 11/406

(52) U.S. Cl. CPC G11C 11/40618; G11C 11/40603; G11C 11/40615

(57) ABSTRACT

A processing-in-memory (PIM) device schedules a refresh operation based on knowledge of an ongoing PIM operation. A memory controller of the PIM device initiates execution of a PIM operation on a first set of memory banks of the memory device. The memory controller selects a second set of memory banks different than the first set of memory banks to execute a refresh operation based on knowledge of the initiating the execution of the PIM operation on the first set of memory banks. The memory controller initiates execution of the refresh operation on the second set of memory banks. The memory controller switches, in response to completing execution of the PIM operation on the first set of memory banks, execution of the refresh operation to the first set of memory banks and execution of the PIM operation to the second set of memory banks.

### TECHNICAL FIELD

This disclosure relates generally to processing-in-memory (PIM) architectures, and more specifically, scheduling a refresh operation based on knowledge of an ongoing PIM operation.

### BACKGROUND

Modern computing systems increasingly handle large-scale matrix computations, particularly in applications such as Large Language Models (LLMs). These computations often require significant memory bandwidth and computational resources. Processing-in-memory (PIM) architectures have emerged as a solution to address the memory bandwidth bottleneck by performing computations closer to where data resides. In PIM architectures, computational units are integrated within memory devices, such as Dynamic Random Access Memory (DRAM), to enable matrix-vector operations to be performed directly within the memory device. This approach can leverage higher memory bandwidth that is available inside the memory device compared to traditional architectures, i.e., where data must be transferred between memory and processor.

The computational units may include PIM units (PUs). In some PIM architectures, the memory devices may be logically divided into memory banks and the memory banks may be associated with PUs. For example, a single PU may manage computations for multiple banks, such as two banks. To manage the computations, the PU may receive a command issued by a host processor (CPU) or the PU may be configured to operate autonomously for the computations. For example, a host processor may send a command to a PU to fetch data from one or more memory banks to perform computations. The PU may be within or proximate the memory banks, such that the PU may efficiently access the data stored in the memory banks and perform the computations on the data. That is, the PU may manage or perform the computations directly on data stored within the memory device, such that data may be processed by the PU within the memory device rather than transferring the data to an external processor for processing.

The memory banks may store data in a vector data structure that includes multiple data elements that may be processed simultaneously. The PU may perform parallel computations using the memory banks associated with the vector. The computations may include multiply-accumulate (MAC) operations and other arithmetic operations. Using a MAC operation as an example, the PU may perform MAC operations in parallel across the memory banks associated with vector. The PIM unit may also include an accumulator, which may be a register or memory location that stores intermediate or final results for the computations.

Often, a PIM operation, which is an operation performed by the processor of the PU using data stored at a memory bank (e.g., real-time data analysis, high-speed data processing, complex calculations on large datasets, etc.) may involve active or “open” memory banks that allow data access at the active memory banks (e.g., access data in a row buffer of a row associated with the open memory bank). In some cases, a memory controller may issue a refresh command, triggering a refresh operation. The refresh operation may involve precharging or “closing” an active bank. That is, the bank is no longer active when refreshed and becomes unavailable, for example, for PIM operations.

In some cases, the memory controller may issue the refresh command for a bank that is preoccupied with an ongoing PIM operation. The refresh may cause the bank to stop the ongoing operations (e.g., operations associated with the PIM), since the refresh operation may be a higher priority operation than the PIM operation. The abrupt stopping of the ongoing PIM operation may result in data loss, as well as result in latencies associated with completing the PIM operation. For example, latencies may increase since memory access is unavailable until the refresh operation is completed and the entire PIM operation is repeated when the bank becomes available.

### SUMMARY

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

The present disclosure describes systems, methods, devices, and apparatuses for scheduling a refresh operation based on knowledge of an ongoing processing-in-memory (PIM) operation. Aspects of the subject matter described in this disclosure may be implemented in a PIM device. The PIM device may include a memory (e.g., a dynamic random access memory (DRAM)) and the memory may be divided into memory banks. The PIM device may include PIM units (PUs) and each of the PUs may manage a respective first bank (e.g., an even bank) and a second bank (e.g., an odd bank) to perform a PIM operation. A PIM operation is an operation performed by the PU using data from a memory bank. A PIM operation may involve multiple banks, such as eight banks. During a PIM operation (e.g., real-time data analysis, high-speed data processing, complex calculations on large datasets, etc.), eight banks may be active or “open” to allow data access for normal PIM operations. For example, eight of the first banks associated with eight PUs may be active banks used during the PIM operation (e.g., banks 0, 2, 4, 6, 8, 10, 12, and 14). During a refresh operation, banks may become unavailable or “closed” for data access.

For the PIM device to execute both a PIM operation and a refresh operation without interrupting either of the operations, which involve different states of the memory banks (e.g., open for a PIM operation and closed for a refresh operation), the memory controller may schedule a per-bank refresh operation at banks that are not associated with the PIM operation. For example, the memory controller may schedule the PIM operation to be executed using eight of the first banks (e.g., banks 0, 2, 4, 6, 8, 10, 12, and 14) associated with the eight PUs while scheduling the refresh operation to be executed using eight of the second banks (e.g., banks 1, 3, 5, 7, 9, 11, 13, and 15) associated with the same eight PUs. A refresh operation at the set of first banks involved in the PIM operation may be disabled. After the PIM operation has finished, the first banks may be available for a refresh operation and the PIM operation (e.g., same or different PIM operation than performed on the first banks) may be executed on the second banks (e.g., switch refresh operation to the set of first banks).

Additionally, or alternatively, to the per-bank refresh operation at banks that are not associated with an ongoing PIM operation, the memory controller may postpone one or more refresh operations to be executed at the banks occupied with the PIM operations. For example, the memory controller may schedule one or more PIM operations (e.g., a PIM batch) to be executed on eight of the first banks associated with the eight PUs by delaying the refresh operations for the first banks up to a postponement threshold. The schedule may result in multiple consecutive PIM operations performed using the eight of the first banks. Once the PIM operations are completed, the postponed refresh operations may be executed using the first banks and/or the second banks prior to executing any additional PIM operations using the first banks and/or the second banks.

Scheduling the refresh operation on memory banks using the per-bank refresh operation and/or postponing of one or more refresh operations based on an awareness of a current PIM operation that is executed using a set of the memory banks may facilitate efficiently executing the PIM operation without interruptions. For example, allowing the PIM operations to be completed may reduce data loss associated with interrupting a PIM operation, as well as reduce delays otherwise associated with repeating PIM operations that were interrupted. Avoiding repeated PIM operations may also reduce energy consumption at the PIM device that is otherwise associated with repeated PIM operations.

In one aspect of the disclosure, a method for scheduling a refresh operation based on knowledge of an ongoing PIM operation includes initiating, by a memory controller of a memory device, execution of a PIM operation on a first plurality of memory banks of the memory device. The method includes selecting, by the memory controller of the memory device, a second plurality of memory banks of the memory device different than the first plurality of memory banks to execute a refresh operation based at least in part on knowledge of the initiating the execution of the PIM operation on the first plurality of memory banks. The method includes initiating, by the memory controller of the memory device, execution of the refresh operation on the second plurality of memory banks. The method includes switching, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

In an additional aspect of the disclosure, an apparatus, such as a PIM device, is disclosed for scheduling a refresh operation based on knowledge of an ongoing PIM operation. The PIM device includes one or more memories storing processor-executable code and one or more processors that are coupled with the one or more memories and individually or collectively operable to execute the code to cause the apparatus to initiate, by a memory controller of a memory device, execution of a PIM operation on a first plurality of memory banks of the memory device. The one or more processors are individually or collectively further operable to execute the code to cause the apparatus to select, by the memory controller of the memory device, a second plurality of memory banks of the memory device different than the first plurality of memory banks to execute a refresh operation based at least in part on knowledge of the initiating the execution of the PIM operation on the first plurality of memory banks. The one or more processors are individually or collectively further operable to execute the code to cause the apparatus to initiate, by the memory controller of the memory device, execution of the refresh operation on the second plurality of memory banks. The one or more processors are individually or collectively further operable to execute the code to cause the apparatus to switch, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

In an additional aspect of the disclosure, a non-transitory computer-readable medium stores instructions that, when executed by a processor, cause the processor to perform operations. The operations include initiating, by a memory controller of a memory device, execution of a PIM operation on a first plurality of memory banks of the memory device. The operations include selecting, by the memory controller of the memory device, a second plurality of memory banks of the memory device different than the first plurality of memory banks to execute a refresh operation based at least in part on knowledge of the initiating the execution of the PIM operation on the first plurality of memory banks. The operations include initiating, by the memory controller of the memory device, execution of the refresh operation on the second plurality of memory banks. The operations include switching, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

These and other implementations may each optionally include one or more of the following features. For instance, various implementations may include disabling execution of the refresh operation on the first plurality of memory banks while the first plurality of memory banks execute the PIM operation. The various implementations may include that each of the first plurality of memory banks and each of the second plurality of memory banks are associated with a single respective processing unit. The various implementations may include that each of the first plurality of memory banks and the second plurality of memory banks comprises eight banks. The various implementations may include selecting the second plurality of memory banks for the refresh operation is performed on a per-bank basis. The various implementations may include incrementing a counter corresponding to pending refresh operations while the first plurality of memory banks executes the PIM operation and the second plurality of memory banks executes the refresh operation. The various implementations, in response to the counter incrementing up to a postponement threshold and the PIM operation completing execution, may include initiating, by the memory controller, execution of the pending refresh operations on one or more memory banks of the first plurality of memory banks, the second plurality of memory banks, or a combination thereof. The various implementations, in response to the completed execution of the pending refresh operations, may include initiating, by the memory controller of the memory device, a second execution of the PIM operation on the first plurality of memory banks of the memory device, and initiating, by the memory controller of the memory device, a second execution of the refresh operation on the second plurality of memory bank after the second execution of the PIM operation completes.

The various aspects, implementations, and features disclosed herein may be implemented in a variety of ways. For example, aspects may be implemented as a device, such as a PIM device, a memory controller, or an integrated circuit. Aspects may also be implemented as one or more methods or processes. Further, aspects may be implemented as instructions stored in a computer-readable storage medium that, when executed by one or more processors, cause the processors to perform the disclosed operations. Such computer-readable storage media may include, but are not limited to, random access memory (RAM), read-only memory (ROM), electrically erasable programmable read-only memory (EEPROM), flash memory or other memory technology, compact disk read-only memory (CD-ROM), digital versatile disks (DVD) or other optical disk storage, magnetic cassettes, magnetic tape, magnetic disk storage or other magnetic storage devices, or any other medium capable of storing instructions for execution by processors.

The various aspects may also be implemented in hardware, software, firmware, or any combination thereof. For instance, aspects may be implemented as dedicated circuits or logic configured to execute the described functionality. Alternatively, or additionally, aspects may be implemented as programs, modules, routines, or other software components executed by one or more processors. In some implementations, aspects may be implemented using application-specific integrated circuits (ASICs), field-programmable gate arrays (FPGAs), or other programmable logic devices.

The details of one or more implementations are set forth in the accompanying drawings and description below. Other features and advantages will be apparent from the description and drawings, and from the claims. It is to be understood that both the foregoing general description and the following detailed description are exemplary and explanatory only and are not restrictive of the invention, as claimed. Features shown in the various figures can be combined and/or modified in ways not explicitly shown, while remaining within the scope of the claims.

### DESCRIPTION OF THE FIGURES

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 shows a block diagram of a processing-in-memory (PIM) system that may be configured for scheduling a refresh operation based on knowledge of an ongoing PIM operation according to one or more aspects of this disclosure.

FIG. 2A shows a block diagram illustrating a basic PIM Dynamic Random Access Memory (DRAM) architecture that can support a PIM operation according to one or more aspects of this disclosure.

FIG. 2B shows an operational flow diagram illustrating the PIM operation processes within the PIM DRAM architecture according to one or more aspects of this disclosure.

FIG. 3 shows an operational flow diagram illustrating how a PIM device supports scheduling a refresh operation based on knowledge of an ongoing PIM operation according to one or more aspects of this disclosure.

FIG. 4 shows an example scheduling diagram illustrating how a PIM device supports scheduling a refresh operation based on knowledge of an ongoing PIM operation according to one or more aspects of this disclosure.

FIG. 5 shows an example scheduling diagram illustrating how a PIM device supports scheduling a refresh operation based on knowledge of an ongoing PIM operation according to one or more aspects of this disclosure.

FIG. 6 shows a flow chart of an example method performed by a PIM device for scheduling a refresh operation based on knowledge of an ongoing PIM operation according to one or more aspects of this disclosure.

FIG. 7 shows a block diagram of an example PIM device configured to scheduling a refresh operation based on knowledge of an ongoing PIM operation according to one or more aspects of this disclosure.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

The present disclosure provides systems, apparatus, methods, and computer-readable media that support scheduling a refresh operation based on knowledge of an ongoing processing-in-memory (PIM) operation. Aspects of this disclosure provide for operations and data structures used in those operations for scheduling a refresh operation based on knowledge of an ongoing PIM operation.

For example, a PIM architecture includes a processor that is integrated with a memory, such as Dynamic Random Access Memory (DRAM), on a single chip. This architecture allows data processing to occur directly within the memory rather than communicating data to a processing unit on a separate chip (e.g., off chip) for subsequent processing. The PIM architecture allows computations to occur closer to where the data is stored, resulting in faster processing speeds and reduced power consumption at the PIM device. Also, the PIM device includes computational units, such as PIM units (PUs). In some PIM architectures, the memory may be logically divided into memory banks and the memory banks may be associated with PUs. For example, a single PU may manage computations for multiple banks, such as two memory banks. In such examples, each of the PUs may manage a respective first bank (e.g., an even bank) and a second bank (e.g., an odd bank).

The DRAM stores capacitors that lose charge overtime due to leakage, and to prevent data loss stored in the DRAM, the capacitors are recharged periodically via a refresh command. A refresh operation involves reading information from a memory bank (e.g., of the DRAM), and immediately rewriting the read information to the same area without modification, for the purpose of preserving the information.

Often, normal PIM operations, such as real-time data analysis, high-speed data processing, complex calculations on large datasets, or other non-refresh operations, may involve active or “open” memory banks that allow data access at the active memory banks (e.g., access data in a row buffer of a row associated with the open memory bank). In some cases, a memory controller may issue a refresh command, triggering a refresh operation. The refresh operation may involve precharging or “closing” an active bank. That is, the bank is no longer active when refreshed and becomes unavailable, for example, for PIM operations.

In some cases, the memory controller may issue the refresh command for a bank that is preoccupied with an ongoing PIM operation. The refresh may cause the bank to stop the ongoing operations (e.g., operations associated with the PIM), since the refresh operation may be a higher priority operation than the PIM operation. The abrupt stopping of the ongoing PIM operation may result in data loss, as well as result in latencies associated with completing the PIM operation. For example, latencies may increase since memory access is unavailable until the refresh operation is completed and the entire PIM operation is repeated when the bank becomes available.

As discussed herein, to schedule a refresh operation based on knowledge of an ongoing PIM operation to avoid latencies and inefficient power consumption at the PIM device, a per-bank refresh operation may be implemented at banks that are not associated with an ongoing PIM operation. For example, the refresh command may be applied to one of the two banks associated with each of the PUs that is not participating in an ongoing PIM operation. Additionally, or alternatively to the per-refresh operation, one or more refresh operations may be postponed until one or more PIM operations have completed, up to a postponement threshold.

In particular, a PIM operation may involve multiple banks, such as eight banks. During a PIM operation (e.g., real-time data analysis, high-speed data processing, complex calculations on large datasets, or other non-refresh operation), eight banks may be active or “open” to allow data access for normal PIM operations. For example, eight of the first banks associated with eight PUs may be active banks used during the PIM operation (e.g., banks 0, 2, 4, 6, 8, 10, 12, and 14). During a refresh operation, banks may become unavailable or “closed” for data access.

For the PIM device to execute both a PIM operation and a refresh operation without interrupting either of the operations, which involve different states of the memory banks (e.g., open for a PIM operation and closed for a refresh operation), the memory controller may schedule a per-bank refresh operation at banks that are not associated with the PIM operation. For example, the memory controller may schedule the PIM operation to be executed using eight of the first banks (e.g., banks 0, 2, 4, 6, 8, 10, 12, and 14) associated with the eight PUs while scheduling the refresh operation to be executed using eight of the second banks (e.g., banks 1, 3, 5, 7, 9, 11, 13, and 15) associated with the same eight PUs. A refresh operation at the set of first banks involved in the PIM operation may be disabled. After the PIM operation has finished, the first banks may be available for a refresh operation and the PIM operation may be executed on the second banks (e.g., switch refresh operation to the set of first banks).

Additionally, or alternatively, to the per-bank refresh operation, the memory controller may postpone one or more refresh operations to be executed at the banks occupied with the PIM operations. For example, the memory controller may schedule one or more PIM operations (e.g., a PIM batch) to be executed on eight of the first banks associated with the eight PUs by delaying the refresh operations for the first banks up to a postponement threshold. The schedule may result in multiple consecutive PIM operations performed using the eight of the first banks. Once the PIM operations are completed, the postponed refresh operations may be executed using the first banks and/or the second banks prior to executing any additional PIM operations using the first banks and/or the second banks.

Scheduling the refresh operation on memory banks using the per-bank refresh operation and/or postponing of one or more refresh operations based on an awareness of a current PIM operation that is executed using a set of the memory banks may facilitate in efficiently executing the PIM operation without interruptions. For example, allowing the PIM operations to be completed may reduce data loss associated with interrupting a PIM operation, as well as reduce delays otherwise associated with repeating PIM operations that were interrupted. Avoiding repeated PIM operations may also reduce energy consumption at the PIM device that is otherwise associated with repeated PIM operations.

The detailed description set forth below, in connection with the appended drawings to which the text references, is intended as a description of various embodiments and is not intended to limit the scope of the disclosure. Rather, the detailed description includes specific details for the purpose of providing a thorough understanding of the subject matter of this disclosure. It will be apparent to those skilled in the art that these specific details are not required in every case and that, in some instances, well-known structures and components are shown in block diagram form for clarity of presentation.

In the description of embodiments herein, numerous specific details are set forth, such as examples of specific components, memory devices, and processes to provide a thorough understanding of the present disclosure. Also, in the following description and for purposes of explanation, specific nomenclature is set forth to provide a thorough understanding of the present disclosure. However, it will be apparent to one skilled in the art that these specific details may not be required to practice the teachings disclosed herein. In other instances, well-known circuits and devices are shown in block diagram form to avoid obscuring teachings of the present disclosure.

Some portions of the detailed descriptions which follow are presented in terms of procedures, logic blocks, processing, and other symbolic representations of operations on data bits within a computer memory. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a processing-in-memory device.

Particular implementations of the subject matter described in this disclosure may be implemented to realize one or more of the following potential advantages or benefits. In some aspects, the present disclosure provides techniques for efficiently executing the PIM operation without interruptions. For example, allowing the PIM operations to be completed may reduce data loss associated with interrupting a PIM operation, as well as reduce delays otherwise associated with repeating PIM operations that were interrupted. Avoiding repeated PIM operations may also reduce energy consumption at the PIM device that is otherwise associated with repeated PIM operations.

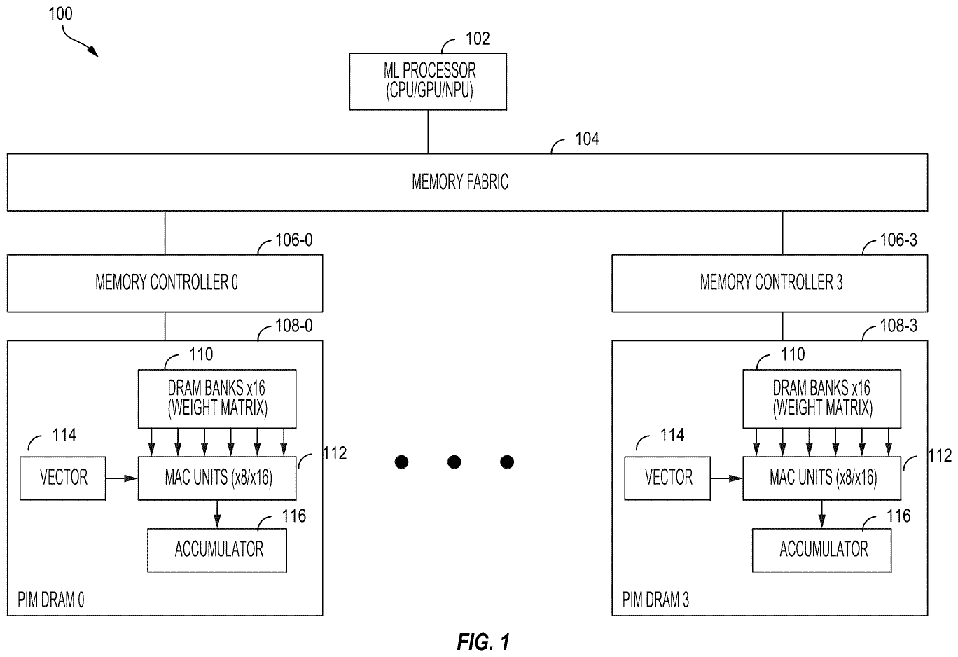

FIG. 1 illustrates a block diagram of a PIM system 100 that enables computation directly within memory devices according to aspects described herein. The PIM system 100 includes a machine learning (ML) processor 102, which may be implemented using various processing architectures. For example, the ML processor 102 may comprise a central processing unit (CPU), graphics processing unit (GPU), neural processing unit (NPU), application-specific integrated circuit (ASIC), or combinations thereof. ML processor 102 can be configured to manage high-level operations, distribute computational tasks, and coordinate processing across memory devices.

A memory fabric 104 couples to ML processor 102 and enables data movement and processing capabilities. Memory fabric 104 can be specialized to support various processing-in-memory operations through command handling, routing protocols, and synchronization mechanisms. The memory fabric 104 may implement different interconnect technologies and topologies depending on system requirements, including point-to-point connections, crossbar switches, or mesh networks.

Memory fabric 104 connects to multiple memory controllers 106 (illustrated as controllers 106-0 through 106-3 in one implementation, though other quantities may be implemented). Each memory controller 106 can be configured to support PIM commands and operations beyond traditional memory access patterns. The memory controllers 106 may implement specialized command queues, reordering logic, and timing control to manage both conventional memory operations and PIM functions. Different implementations may employ varying numbers of controllers based on factors such as system size, bandwidth requirements, and power constraints. It is noted that PIM DRAM has been described by way of illustration, rather than limitation and that other memories may be used with the techniques described herein.

Each memory controller 106 couples to a corresponding PIM DRAM 108 device. While four PIM DRAM devices (108-0 through 108-3) are shown, systems may scale from single devices to large arrays of devices. Each PIM DRAM 108 includes multiple DRAM banks 110, which may be implemented in various configurations (for example, eight, sixteen, or thirty-two banks per device). The DRAM banks 110 can be configured to store different types of data, including weight matrices for neural network computations, activation values, or general computational data structures. DRAM banks 110 may be organized into different zones or regions optimized for specific access patterns or computational requirements.

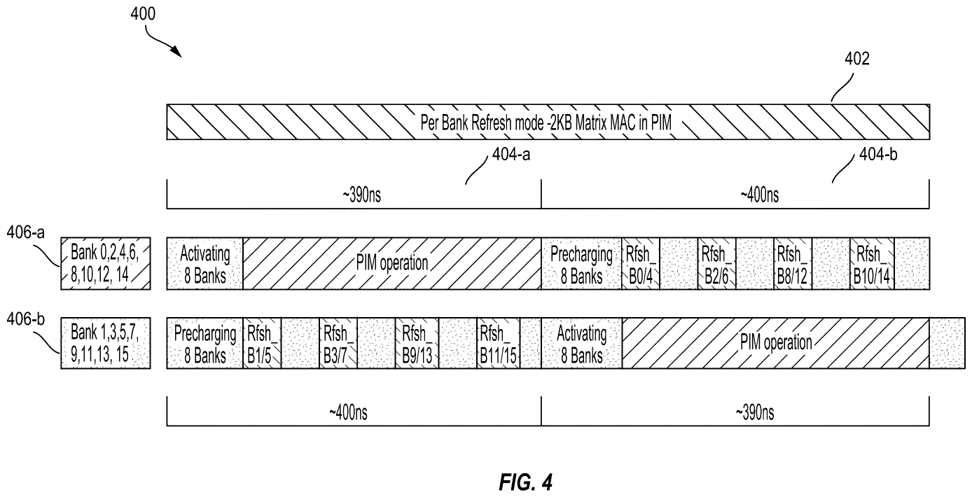

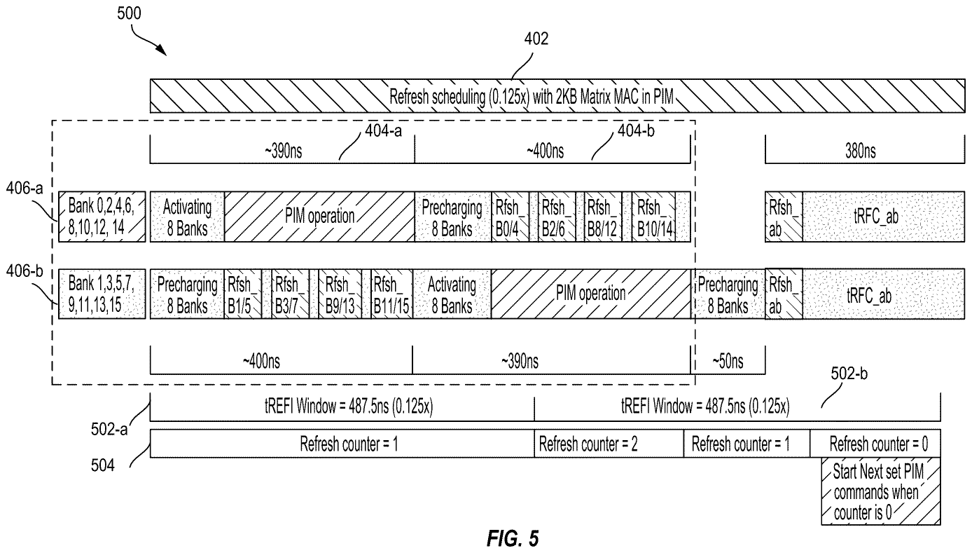

As discussed herein, and as discussed in detail with respect to FIG. 4 and FIG. 5, the DRAM banks 110 may be used in a PIM operation. The memory controller 160 (e.g., memory controller 160-0 controlling PIM DRAM 108) may schedule a refresh operation on the DRAM banks 110 based on the knowledge of the ongoing PIM operation.

Within each PIM DRAM 108, multiply-accumulate (MAC) units 112 couple to DRAM banks 110 and can be configured to perform various computational operations, which may be PIM operations (e.g., from basic multiplication and accumulation to more complex functions). The number and capability of MAC units 112 may vary by implementation, with configurations ranging from four to thirty-two units being common examples. MAC units 112 can support multiple precision formats (for example, 4-bit, 8-bit, 16-bit operations) and various operational modes, including Single Instruction Multiple Data (SIMD) execution where a single command triggers parallel execution across all units within a device.

Vector interfaces 114 provide input paths for vector data into MAC units 112. These interfaces can support different data widths and formats, enabling flexible handling of input vectors. Vector accumulators 116 couple to MAC units 112 in each PIM DRAM 108 and can be configured with varying bit widths and accumulation depths based on application requirements.

The system supports sophisticated execution models across different hierarchical levels. Within each PIM DRAM 108, SIMD execution enables efficient parallel processing across MAC units. Across different PIM DRAM 108 devices, Multiple Instruction Multiple Data (MIMD) execution allows independent operations to proceed in parallel, which are managed through software orchestration via spawn and synchronization mechanisms controlled by ML processor 102.

Memory controllers 106 may implement complex coordination mechanisms to manage both traditional memory access as well as PIM operations. This can include specialized command scheduling, resource allocation, and synchronization across multiple devices. As discussed herein, the command scheduling may include a refresh command that is scheduled based on awareness of one or more ongoing PIM operations to allow the PIM operations to be completed before implementing the refresh command.

The architecture enables significant bandwidth improvements compared to traditional approaches by minimizing data movement between memory and processing units. In operation, the PIM system 100 can handle diverse computational workloads by distributing operations across multiple PIM DRAM 108 devices. Data structures may be partitioned and distributed across DRAM banks 110 in various ways depending on application requirements. For example, a PIM operation may be distributed across 8 DRAM banks 110. The architecture supports different scaling approaches, from small embedded systems to large computational arrays, while maintaining the benefit of performing computations close to data storage.

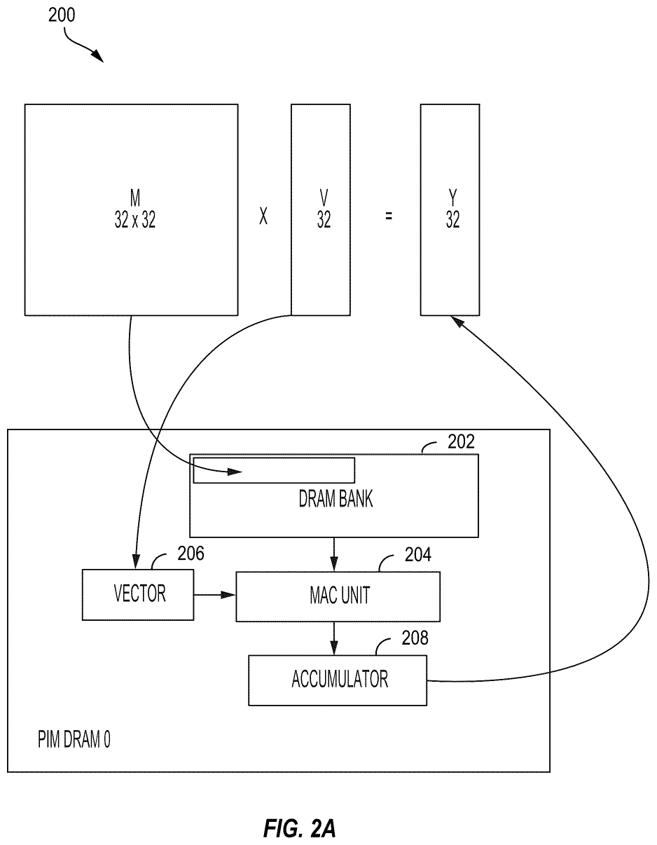

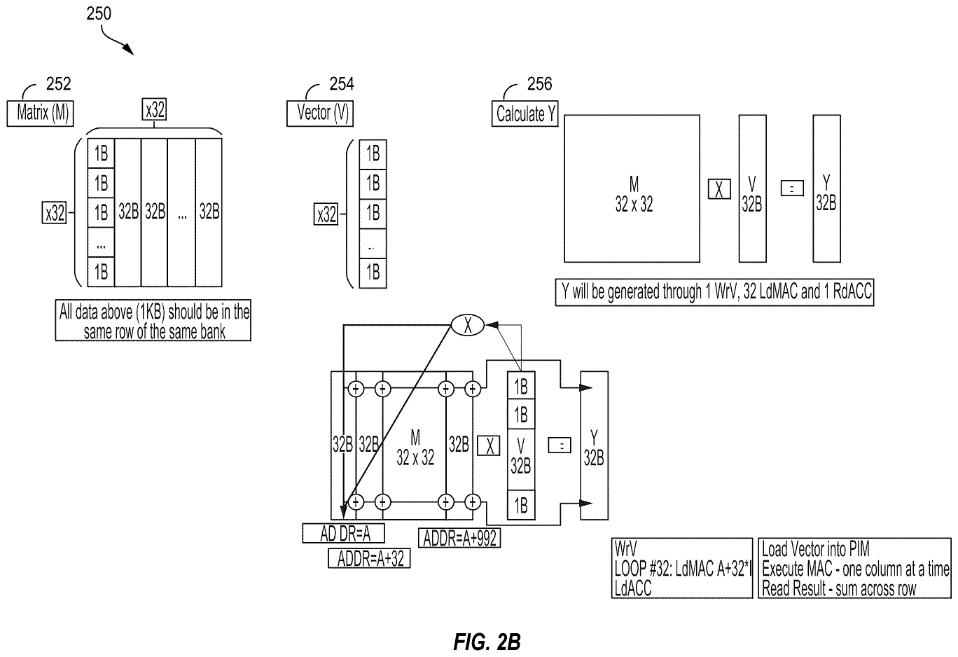

FIGS. 2A and 2B illustrate PIM operation fundamentals that can support efficient PIM operations, such as matrix computations, including block quantization techniques for neural network processing, according to aspects described herein. Although the descriptions discussed herein describe a PIM operation including matrix computations and block quantization, a PIM operation may include other computations or non-refresh operations. FIG. 2A shows a basic PIM DRAM architecture 200 while FIG. 2B illustrates the corresponding operational flow diagram 250 of matrix-vector multiplication within the architecture.

Referring to FIG. 2A, a PIM DRAM architecture 200 can include a DRAM bank 202 configurable to store matrix data, such as neural network weight matrices. In mobile or resource-constrained systems, these weights may be stored in reduced precision formats, such as 4-bit values, to minimize memory footprint. A MAC unit 204 can couple to DRAM bank 202 and may process matrix values along with vector inputs. Vector register 206 can provide storage for input vectors and may couple to MAC unit 204. An accumulator register 208 can couple to MAC unit 204 and may store operation results.

FIG. 2B details the operational flow diagram 250 of a PIM operation, such as a matrix-vector multiplication, within architecture 200. A weight matrix (M) 252 can be arranged as a 32×32 matrix occupying, for example, 1 kilobyte (KB) of memory in DRAM bank 202, though other sizes and arrangements may be implemented. An input vector (V) 254 may include 32 elements stored in vector register 206, with the size being configurable based on implementation requirements. The multiplication operation produces a result vector (Y) 256 that can be stored in accumulator register 208.

The operational sequence can begin with a Write Vector (WrV) operation that loads input data into vector register 206. After activating the appropriate DRAM page, the system can perform a series of Load and MAC (LdMAC) operations, processing one matrix column at a time through MAC unit 204. Results may accumulate in accumulator register 208 and can be accessed through Load Accumulator (LdACC) operations.

Architecture 200 can support various block quantization techniques that enable efficient processing of LLMs and the like. Weight matrices may be organized into blocks, with each block potentially sharing scaling factors that map reduced-precision values to larger numerical ranges. For example, blocks of 32 weights can share a scaling factor, enabling efficient storage while maintaining computational accuracy through appropriate scaling operations.

Multiple block quantization implementations can be realized through this architecture. In one approach, weights may be partitioned into blocks of 32 values sharing a floating-point scale factor, with activation values dynamically quantized to 8-bit precision in similarly-sized blocks. Another approach implements hierarchical quantization by aggregating multiple blocks (e.g., combining eight 32-weight blocks into 256-value superblocks). This hierarchical structure can enable use of reduced 6-bit block scale factors alongside a single floating-point scale factor for the superblock, potentially improving both storage efficiency and computational throughput.

The architecture of FIG. 2A can enable the foregoing quantization approaches (as well as other PIM operations) through its structured processing capabilities. For example, when implementing hierarchical quantization, DRAM bank 202 can store both weight blocks and their associated scaling factors in an organized layout that matches the computational flow through MAC unit 204. The accumulator register 208 can be configured to maintain sufficient precision to handle intermediate results before final scaling operations are applied.

In one implementation, superblock sizes may be increased up to 1024 elements to better balance computational efficiency with accuracy. The architecture can support such scaling through its memory organization and computational paths. Integer arithmetic may be used extensively within the PIM device itself, thereby limiting more complex floating-point operations to final scaling steps performed outside the core computation loop.

The relationship between memory organization and computation shown in FIG. 2B is important for efficient block quantization. The structured addressing pattern (A, A+32, etc.) can enable regular access to both weight values and scaling factors. When processing hierarchical blocks, the system can maintain alignment between weight values and their corresponding scale factors at multiple granularities. This organization may support various computational patterns, from basic matrix-vector multiplication to sophisticated quantized neural network operations.

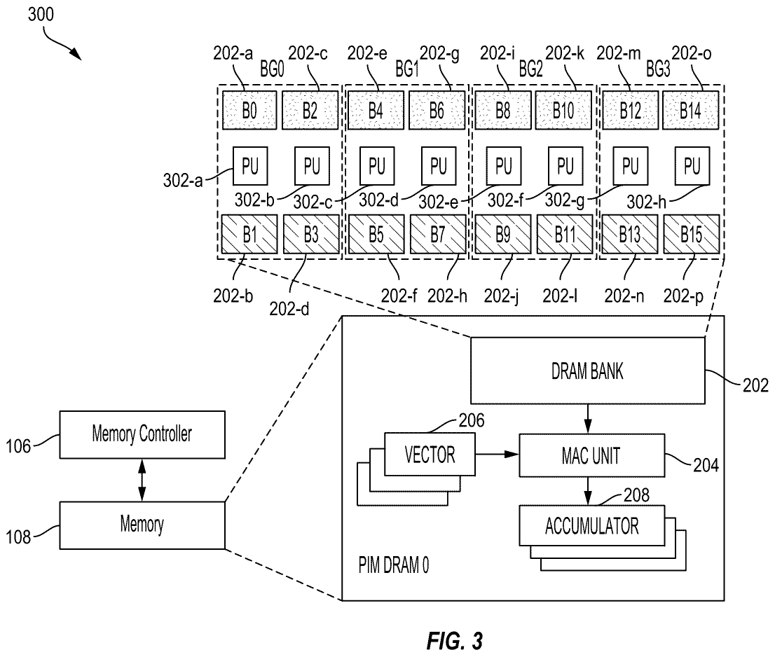

FIG. 3 shows an operational flow diagram 300 illustrating how a PIM device supports scheduling a refresh operation based on knowledge of an ongoing PIM operation according to one or more aspects of this disclosure. The process shown by the operational flow diagram 300 provides mechanisms for managing PIM operations and refresh operations implemented using memory banks within memory devices. A PIM device may implement process through various hardware and software components working together to perform the scheduling while maintaining computational efficiency.

The PIM device may include a memory controller 106 that controls the DRAM 108, which includes a DRAM bank 202, a vector register 206, a MAC unit 204, and an accumulator register 208 that may operate as discussed with respect to FIGS. 1, 2A, and 2B.

As shown in FIG. 3, a memory controller 106 may bidirectionally communicate with the memory, such as DRAM 108. In particular, the memory controller 106 send a command to the DRAM 108, to implement the command. In some examples, the memory controller 106 may issue a refresh command to one or more banks of the DRAM bank 202, while the one or more banks are participating in a PIM operation.

As shown, the DRAM 108 may be divided into multiple DRAM banks 202. In the depicted embodiment, the DRAM 108 is divided into 16 DRAM banks 202, but the DRAM 108 may be divided into greater or fewer banks. Here, the DRAM banks 202 include a first DRAM bank 202-a (B0), a second DRAM bank 202-b (B1), a third DRAM bank 202-c (B2), and a fourth DRAM bank 202-d (B3) as part of a first bank group (BG0), as well as a fifth DRAM bank 202-e (B4), a sixth DRAM bank 202-f (B5), a seventh DRAM bank 202-g (B6), and an eighth DRAM bank 202-h (B7) as part of a second bank group (BG1). The DRAM banks 202 include a ninth DRAM bank 202-i (B8), a tenth DRAM bank 202-j (B9), an eleventh DRAM bank 202-k (B10), and a twelfth DRAM bank 202-l (B11) as part of a third bank group (BG2), as well as a thirteenth DRAM bank 202-m (B12), a fourteenth DRAM bank 202-n (B13), a fifteenth DRAM bank 202-o (B14), and a sixteenth DRAM bank 202-p (B15) as part of a fourth bank group (BG3).

The DRAM banks 202 may be managed by PUs 302. In particular, the PUs 302 may each manage the computation of the two DRAM banks 202, such as a first DRAM bank (e.g., a first memory bank or even bank that is indicated by a dot pattern box) and a second DRAM bank (e.g., a second memory bank or an odd bank that is indicated by a denser dot pattern box). For example, a first PU 302-a may manage the first DRAM bank 202-a and the second DRAM bank 202-b. A second PU 302-b may manage the third DRAM bank 202-c and the fourth DRAM bank 202-d. A third PU 302-c may manage the fifth DRAM bank 202-e and the sixth DRAM bank 202-f. A fourth PU 302-d may manage the seventh DRAM bank 202-g and the eighth DRAM bank 202-h. A fifth PU 302-e may manage the ninth DRAM bank 202-i and the tenth DRAM bank 202-j. A sixth PU 302-f may manage the eleventh DRAM bank 202-k and the twelfth DRAM bank 202-l. A seventh PU 302-g may manage the thirteenth DRAM bank 202-m and the fourteenth DRAM bank 202-n. An eight PU 302-h may manage the fifteenth DRAM bank 202-o and the sixteenth DRAM bank 202-p. The first banks (e.g., even banks) may include B0, B2, B4, B6, B8, B10, B12, and B14. The second banks (e.g., odd banks) may include B1, B3, B5, B7, B9, B11, B13, and B15.

Often, the eight PUs 302 may use eight banks for a PIM operation, where the banks are active and open at the same time to allow loading data from eight banks for execution the PIM operation. Accordingly, in the depicted embodiment, each of the first or even DRAM banks 202 (B0, B2, B4, B6, B8, B10, B12, and B14) may be active banks or each of the second or odd DRAM banks 202 (B1, B3, B5, B7, B9, B11, B13, and B15) may be active banks. Although the following descriptions describe the PIM operation or the refresh command using the first DRAM banks 202 or the second bank, a combination of the first banks and the second banks may be used. For example, any single first or second bank of a respective PU 302 may be used for a PIM operation.

Meanwhile, the memory controller 106 may issue a refresh command to maintain the data in DRAM 108. Refresh to one of the eight DRAM banks 202 executing the PIM operation may interrupt the PIM process, resulting in a delay (e.g., 230 nanoseconds (ns)) before reactivating the same DRAM bank 202 in order to restart and complete the PIM operation, resulting in additional delay. Moreover, delaying the refresh operation may violate the DRAM data refresh requirement, such as by exceeding a refresh operation postponement threshold. As described in detail with respect to FIG. 4, the memory controller 106 may efficiently maintain expected performance of PIM operation processing while also completing the refresh command in time.

Moreover, in some examples, the PIM operation may be a matrix MAC calculation, such as a 2 KB matrix MAC calculation. In such examples, the PIM operation may take 400 ns to complete, and thus, the eighth banks are to remain open for the 400 ns for the PIM operation to complete. For a refresh operation having a high refresh rate (e.g., 0.125×, time interval between refresh commands (tREFI)=487.5 ns), the remaining 87.5 ns may not be enough time to complete the refresh operation while meeting the refresh cycle time (tRFC) timing. Briefly, and as discussed in detail with respect to FIG. 5, the memory controller 106 may efficiently complete the PIM operation processing while also fulfilling the refresh requirement in 0.125× refresh rate by applying the refresh operation to per-bank to the banks not used for the ongoing PIM operation.

FIG. 4 shows an example scheduling diagram 400 illustrating how a PIM device supports scheduling a refresh operation based on knowledge of an ongoing PIM operation according to one or more aspects of this disclosure. As discussed herein, the memory controller may issue a refresh command to maintain data in memory but refreshing one or more banks implementing the PIM operation may interrupt the process, resulting in delays. For example, precharging or closing the active bank may result in 230 ns delay. Moreover, reimplementing the entire PIM operation results in additional delay.

Here, the PIM device is operating in a per-bank refresh mode to implement a PIM operation, such as implementing a 2 KB matrix MAC calculation 402 (e.g., matrix computation as discussed with respect to FIG. 2A and FIG. 2B). Multiple PIM operations and/or refresh operations, such as two, four, etc. PIM operations may be executed for the matrix MAC calculation 402 (e.g., two PIM operations and two refresh operations are shown). The 2 KB matrix MAC calculation 402 may include a first portion 404-a of the PIM operations and a second portion 404-b of the PIM operations. During the first portion 404-a and the second portion 404-b, a PIM operation (e.g., the operation and activation of banks) may take 390 ns and a refresh operation (e.g., pre-charging and refreshing of banks) may take 400 ns. Thus, completing the refresh operations on all banks for the 2 KB matrix MAC calculation 402 may take 800 ns and 780 ns for completing the PIM operations on all the banks.

To allow a PIM operation to complete without interruption while also executing the refresh command to meet refresh constraints, and to reduce delays associated with interrupting a PIM operation, the techniques discussed herein include scheduling per-bank refresh on banks that are not participating in and/or executing a PIM operation (e.g., operation performed by a PIM unit (PU)). To illustrate, FIG. 4 depicts activating a first set of eight active banks 406-a, banks B0, B2, B4, B6, B8, B10, B12, B14 (e.g., DRAM banks 202 of FIG. 3) and executing a PIM operation on the eight active banks during the first portion 404-a.

During the activation, a second set of eight banks 406-b including banks B1, B3, B5, B7, B9, B11, B13, and B15 (e.g., DRAM banks 202 of FIG. 3) may be pre-charged for executing a refresh operation. In particular, the second set of eight banks 406-b may be used to implement the refresh operation since the second set of eight banks 406-b are not used in the ongoing PIM operation. The second set of eight banks 406-b may be selected per-bank for the refresh. While the first set of banks 406-a (e.g., B0, B2, B4 . . . B12) execute the PIM commands, the second set of banks 406-b (e.g., B1, B3, B5 . . . B15) may execute the refresh command at the same time. To ensure that the PIM operation is completed, refresh to the first set of banks 406-a may be blocked during the first portion 404-a and/or while the PIM operation is executing. As shown during the second portion 404-b, once the first set of banks 406-a finish executing the PIM operation, the first set of banks 406-a may start to refresh and the second set of banks 406-b may execute the PIM operation (e.g., the same or a different PIM operation). That is, executing the refresh operation and the PIM operation may switch from the first set of banks 406-a to the second set of banks-b, and vice versa, to complete the refresh operation on each of the banks (B0, B1, B2. . . B15) while simultaneously performing calculations via the PIM operations.

FIG. 5 shows an example scheduling diagram 500 illustrating how a PIM device supports scheduling a refresh operation based on knowledge of an ongoing PIM operation according to one or more aspects of this disclosure. Some PIM operations, such as the 2 KB Matrix MAC calculation 402, may take approximately 400 ns to complete. During the approximately 400 ns, all eight banks are to remain open. The PIM operations and the refresh operations during the first portion 404-a and the second portion 404-b may operate as discussed with FIG. 5 (and indicated by the dashed line box).

In some cases, such as a high refresh rate case, a cycle of an operation may not be long enough to comply with a tRFC. Here, a first refresh interval time (tREFI) window may be 487.5 nm when the refresh rate is 0.125×. However, the refresh operation applied to all banks (e.g., B0, B1, B2. . . B15) may take longer than 487.5 ns. For example, the refresh operation is executed on the second set of banks 406-b in approximately 400 ns (e.g., 487.5 ns tREFI window- 400 ns refresh to the second set of banks=87.5 ns), and 87.5 ns may be too short of a duration to execute the refresh operation on the first set of banks 406-a (e.g., to complete the refresh operation on all banks). The techniques discussed herein include the memory controller allow the PIM operation to complete while also filling the refresh operation constraints associated with a high refresh rate, such as the 0.125× refresh case. In particular, the memory controller may allow one or more PIM operations to complete while the refresh commands are postponed (e.g., in queue) up to a postponement threshold for the refresh operation.

To illustrate, a first tREFI window 502-a is 487.5 ns and as previously discussed, the refresh operation may take 400 ns on the second set of banks 406-b while the PIM operation completes, and 87.5 ns is not a long enough duration to execute the refresh operation on the first set of banks 406-a. A counter may be used to track the quantity of refresh operations that are not completed on all the banks while the PIM operations are completed, effectively prioritizing the PIM operations over the refresh operation, which is often higher priority. Since the refresh operation did not complete by the end of the first tREFI window 502-a, a refresh counter 504 may increment to one. During a second tREFI window 502-b, the refresh counter 504 may increment to two since the refresh operation did not finish on all banks prior to the first tREFI window 502-a expiring. However, during the second portion 404-b, the refresh operation may finish executing on the first set of banks 406-a and the second set of banks 406-b, such that all the banks have been refreshed. Accordingly, after the second portion 404-b, the refresh counter 504 may decrement back to one prior to expiration of the second tREFI window 502-b.

In some examples, the postponement threshold may be eight, such less than or equal to eight refresh commands may be postponed. The PIM operation may be executed on the banks as discussed with respect to FIG. 4, up to the postponement threshold. Once the programmable PIM batches are completed, the memory controller will execute the postponed refresh commands on the banks prior to any subsequent execution of PIM operations (e.g., not start new PIM commands before pending refresh commands are all cleared).

Since the refresh counter 504 indicates that one refresh command has been postponed, and the PIM operations have completed, the memory controller may execute the one refresh operation. Thus, both the first set of banks 406-a and the second set of banks 406-b may execute the refresh operation prior to executing additional PIM operations on either set of banks 406. For example, once the refresh counter 504 indicates that no refresh operations are postponed (e.g., counter=0), then additional PIM operations may be executed.

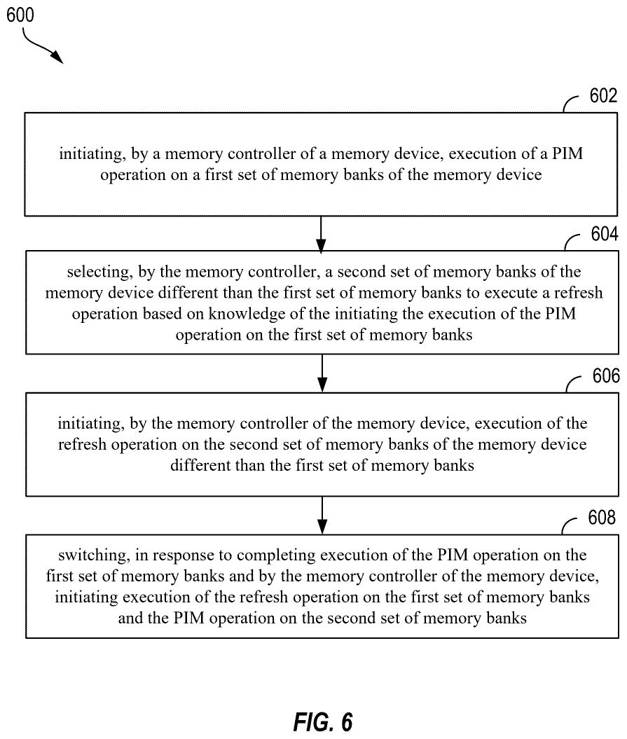

FIG. 6 shows a flow chart of an example method performed by a PIM device for scheduling a refresh operation based on knowledge of an ongoing PIM operation according to one or more aspects of this disclosure. For example, completing the PIM operation on each of the banks may be prioritized with respect to other operations to avoid interruptions in a PIM operation that may otherwise result in delays discussed herein.

In the following description of a process 600, the operations performed by the memory controller may be performed in different orders or at different times than the exemplary order shown. Some operations may also be omitted from the process 600, or other operations may be added to the process 600. Further, while operations in the process 600 are illustrated as being performed by the memory controller (e.g., memory controller 106 of FIG. 3), the examples herein are not to be construed as limiting, as the described features may be associated with any quantity of different device.

At block 602, the process 600 may include initiating, by a memory controller of a memory device, execution of a PIM operation on a first set of memory banks of the memory device (e.g., even DRAM banks 202 of FIG. 3). In some examples, each of the first set of memory banks and each of the second set of memory banks are associated with a common single respective PU (e.g., PU 302 of FIG. 3). In some examples, each of the first set of memory banks and the second set of memory banks may include eight banks.

At block 604, the process 600 may include selecting, by the memory controller, a second set of memory banks of the memory device different than the first set of memory banks to execute a refresh operation based on knowledge of the initiating the execution of the PIM operation on the first set of memory banks. At block 606, the process 600 may include initiating, by the memory controller of the memory device, execution of a refresh operation on the second set of memory banks of the memory device different than the first set of memory banks. In some example, the process 600 may include disabling execution of the refresh operation on the first set of memory banks while the first set of memory banks execute the PIM operation. In some examples, selecting the second set of memory banks for the refresh operation is performed on a per-bank basis. For example, a bank associated with a PU may be selected for the refresh operation since the other bank associated with the same PU is executing a PIM operation. Similar per-bank selections may be made for other PUs. The refresh operation may be performed per bank on each of the selected banks.

At block 608, the process 600 may include switching, in response to completing execution of the PIM operation on the first set of memory banks and by the memory controller of the memory device, initiating execution of the refresh operation on the first set of memory banks and the PIM operation on the second set of memory banks. In some examples, the process 600 may include incrementing a counter corresponding to pending refresh operations while the first set of memory banks executes the PIM operation and the second set of memory banks executes the refresh operation. In such examples, the process 600 may include initiating, by the memory controller, execution of the pending refresh operations on one or more memory banks of the first set of memory banks or the second set of memory banks when the counter indicates at least one pending refresh operation and the PIM operation finishes executing. In response to the completed execution of the pending refresh operations, the process 600 may include initiating, by the memory controller of the memory device, a second execution of the PIM operation on the first set of memory banks of the memory device. The process 600 may also include initiating, by the memory controller of the memory device, a second execution of the refresh operation on the second set of memory banks after the second execution of the PIM operation completes.

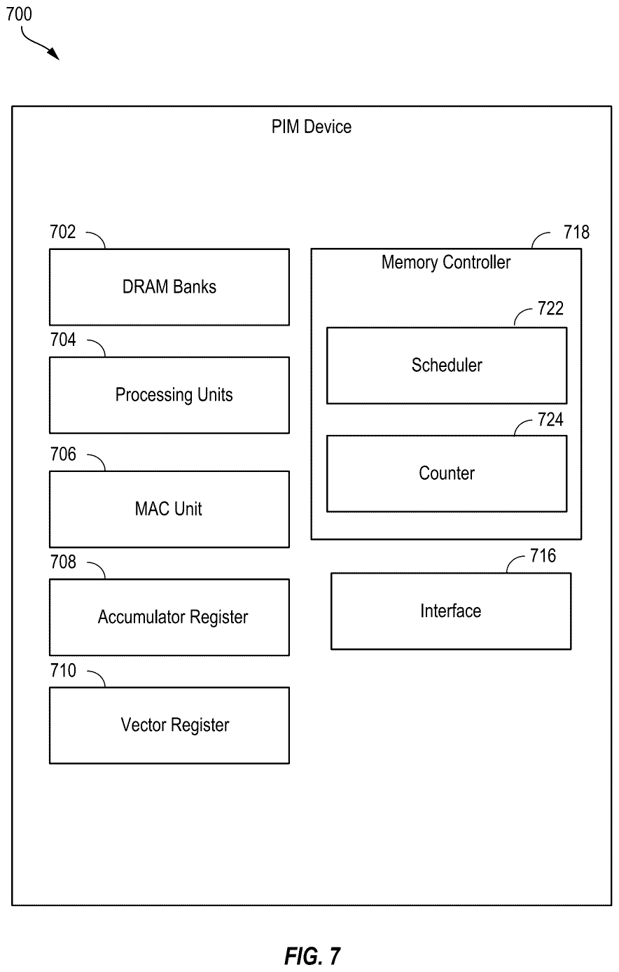

FIG. 7 shows a block diagram of an example PIM device 700 configured to schedule a refresh operation based on knowledge of an ongoing PIM operation according to one or more aspects of this disclosure, such as by perform one or more aforementioned techniques or processes (e.g., process 600).

The PIM device 700 includes one or more DRAM banks 702 configured to execute PIM operations, as discussed herein. PIM device 700 includes one or more DRAM banks 702 (such as, for example, DRAM bank 202) are configured to store data, such as weight matrices and input vectors, for example, to perform PIM operations. Each DRAM bank 702 couples to a MAC unit 706 (such as, for example, MAC unit 204) through a data bus that enables transfer of matrix portions and vector data. The MAC unit 706 performs matrix-vector multiplication operations (e.g., PIM operations) on data retrieved from DRAM bank 702. The PIM device 700 includes a vector register 710 (such as, for example, vector register 206) configured to store input vectors during processing. An accumulator register 708 (such as, for example, accumulator register 208) couples to MAC unit 706 through a dedicated path and accumulates results from matrix-vector operations.

The PIM device 700 includes PUs 704 that operate as discussed with respect to FIG. 3. For example, each of the PUs 704 may manage a respective first bank (e.g., an even bank) and a second bank (e.g., an odd bank). In particular, the PU may interact with a memory bank to perform computations directly within or near the memory, reducing data transfer overhead and latency.

The memory controller 718 (such as, for example, memory controller 106) coordinates operations across the PIM device 700 through a control bus. The memory controller 718 may include a scheduler 722 that can schedule refresh operations based on an awareness of ongoing PIM operations executed, for example, to avoid interruptions in the PIM operation processing that ultimately result in data loss and processing delays. For example, the memory controller 718 may schedule a per-bank refresh operation at banks that are not associated with the PIM operation, as well postpone refresh operations up to a threshold while executing one or more PIM operations, as discussed with respect to FIG. 4 and FIG. 5. The memory controller 718 may include or control a counter 724. The counter may store and update a numerical value that represents a count of occurrences or operations, such as the count of postponed refresh operations. In some examples, the counter may be a memory location or a register used to store the numerical value.

In some examples, the PIM device 700 may further include an interface unit 716 that enables communication with external devices and/or processors. For example, in some embodiments, one or more memory hosts associated with the memory controller 718. For example, a memory host (e.g., external processor) may interact with and control the memory controller 718 to facilitate the scheduling.

In operation, PIM device 700 performs process 600 by having the memory controller 718 initiate execution of a PIM operation (e.g., 2 KB matric MAC) on a first set of memory banks (e.g., even banks B0, B2, B4, B6, B8, B10, B12, B14) of the memory device (block 602 of FIG. 6). The PIM device 700 performs process 600 by having the memory controller 718 selecting, by the memory controller of the memory device, a second set of memory banks of the memory device different than the first set of memory banks to execute a refresh operation based on knowledge of the initiating the execution of the PIM operation on the first set of memory banks (block 604 of FIG. 6).

The PIM device 700 performs process 600 by having the memory controller 718 initiating, by the memory controller of the memory device, execution of the refresh operation on a second set of memory banks (e.g., odd banks B1, B3, B5, B7, B9, B11, B13, B15) of the memory device different than the first set of memory banks (block 606 of FIG. 6) The PIM device 700 performs process 600 by having the memory controller 718 switch, in response to completing execution of the PIM operation on the first set of memory banks and by the memory controller of the memory device, initiating execution of the refresh operation on the first set of memory banks and the PIM operation on the second set of memory banks (block 608 of FIG. 6).

It should be appreciated that PIM device 700 includes means for performing steps to execute process 600. In one implementation, PIM device 700 includes means for initiating, by a memory controller of a memory device, execution of a PIM operation on a first set of memory banks of the memory device. The PIM device 700 further includes means for initiating, by the memory controller of the memory device, execution of a per-bank refresh operation on a second set of memory banks of the memory device different than the first plurality of memory banks. The PIM device 700 further includes means for switching, in response to completing execution of the PIM operation on the first set of memory banks and by the memory controller of the memory device, initiating execution of the refresh operation on the first set of memory banks and the PIM operation on the second set of memory banks.

In one or more aspects, techniques for scheduling a refresh operation based on knowledge of an ongoing PIM operation may include additional aspects, such as any single aspect or any combination of aspects described below or in connection with one or more other processes described elsewhere herein. Additionally, an apparatus may perform or operate according to one or more aspects as described below. In some implementations, the apparatus includes a PIM device. In some implementations, the apparatus includes at least one processor and a memory coupled to the processor. The processor may be configured to perform operations described herein with respect to the apparatus. In some other implementations, the apparatus may include a non-transitory computer-readable medium having program code recorded thereon, the program code being executable by a computer for causing the computer to perform operations described herein. In some implementations, the apparatus may include one or more means configured to perform operations described herein.

In one or more aspects, techniques for scheduling a refresh operation based on knowledge of an ongoing PIM operation, may include additional aspects, such as any single aspect or any combination of aspects described below or in connection with one or more other processes or devices described elsewhere herein.

In a first aspect, an apparatus, which may be a PIM device, may include one or more memories storing processor-executable code, and one or more processors coupled with the one or more memories and individually or collectively operable to execute the code to cause the apparatus to: initiate, by a memory controller of a memory device, execution of a PIM operation on a first plurality of memory banks of the memory device; select, by the memory controller of the memory device, a second plurality of memory banks of the memory device different than the first plurality of memory banks to execute a refresh operation based at least in part on knowledge of the initiating the execution of the PIM operation on the first plurality of memory banks; initiate, by the memory controller of the memory device, execution of the refresh operation on the second plurality of memory banks; and switch, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

In a second aspect, in combination with the first aspect, the one or more processors are individually or collectively further operable to execute the code to cause the apparatus to disable execution of the refresh operation on the first plurality of memory banks while the first plurality of memory banks execute the PIM operation.

In a third aspect, in combination with one or more of the first aspect or the second aspect, each of the first plurality of memory banks and each of the second plurality of memory banks are associated with a single respective processing unit.

In a fourth aspect, in combination with one or more of the first aspect through the third aspect, each of the first plurality of memory banks and the second plurality of memory banks comprises eight banks.

In a fifth aspect, in combination with one or more of the first aspect through the fourth aspect, wherein to select the second plurality of memory banks for the refresh operation is performed on a per-bank basis.

In a sixth aspect, in combination with one or more of the first aspect through the fifth aspect, the one or more processors are individually or collectively further operable to execute the code to cause the apparatus to increment a counter corresponding to pending refresh operations while the first plurality of memory banks executes the PIM operation and the second plurality of memory banks executes the refresh operation.

In a seventh aspect, in combination with one or more of the first aspect through the sixth aspect, and in response to the counter incrementing up to a postponement threshold and the PIM operation completing execution, the one or more processors are individually or collectively further operable to execute the code to cause the apparatus to initiate, by the memory controller, execution of the pending refresh operations on one or more memory banks of the first plurality of memory banks, the second plurality of memory banks, or a combination thereof.

In an eighth aspect, in combination with one or more of the first aspect through the seventh aspect, wherein, in response to the completed execution of the pending refresh operations, the one or more processors are individually or collectively further operable to execute the code to cause the apparatus to initiate, by the memory controller of the memory device, a second execution of the PIM operation on the first plurality of memory banks of the memory device; and initiate, by the memory controller of the memory device, a second execution of the refresh operation on the second plurality of memory bank after the second execution of the PIM operation completes.

In the figures, a single block may be described as performing a function or functions. The function or functions performed by that block may be performed in a single component or across multiple components, and/or may be performed using hardware, software, or a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example devices may include components other than those shown, including well-known components such as a processor, memory, and the like.

Unless specifically stated otherwise as apparent from the following discussions, it should be appreciated that throughout this disclosure, discussions using terms such as “accessing,” “receiving,” “sending,” “using,” “selecting,” “determining,” “normalizing,” “multiplying,” “averaging,” “monitoring,” “comparing,” “applying,” “updating,” “measuring,” “deriving,” “settling,” “generating,” or the like, refer to the actions and processes of a computer system, or similar electronic computing device, that manipulates and transforms data represented as physical (electronic) quantities within the computer system's registers and memories into other data similarly represented as physical quantities within the computer system's registers, memories, or other such information storage, transmission, or display devices. The use of different terms referring to actions or processes of a computer system does not necessarily indicate different operations. For example, “determining” data may refer to “generating” data. As another example, “determining” data may refer to “retrieving” data.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as, e.g., “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (e.g., application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to the Figures referenced above include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits, and processes described above. Whether such functionality is implemented in hardware or software depends upon the particular application and design constraints imposed on the overall system.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or algorithm disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc wherein disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

1. A method for supporting completion of a processing-in-memory (PIM) operation without interruption, comprising:
initiating, by a memory controller of a memory device, execution of a PIM operation on a first plurality of memory banks of the memory device;
selecting, by the memory controller of the memory device, a second plurality of memory banks of the memory device different than the first plurality of memory banks to execute a refresh operation based at least in part on knowledge of the initiating the execution of the PIM operation on the first plurality of memory banks; and
initiating, by the memory controller of the memory device, execution of the refresh operation on the second plurality of memory banks; and
switching, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

2. The method of claim 1, further comprising:
disabling execution of the refresh operation on the first plurality of memory banks while the first plurality of memory banks execute the PIM operation.

3. The method of claim 1, wherein each of the first plurality of memory banks and each of the second plurality of memory banks are associated with a single respective processing unit.

4. The method of claim 1, wherein each of the first plurality of memory banks and the second plurality of memory banks comprises eight banks.

5. The method of claim 1, wherein selecting the second plurality of memory banks for the refresh operation is performed on a per-bank basis.

6. The method of claim 1, further comprising:
incrementing a counter corresponding to pending refresh operations while the first plurality of memory banks executes the PIM operation and the second plurality of memory banks executes the refresh operation.

7. The method of claim 6, wherein, in response to the counter incrementing up to a postponement threshold and the PIM operation completing execution, the method further comprises:
initiating, by the memory controller, execution of the pending refresh operations on one or more memory banks of the first plurality of memory banks, the second plurality of memory banks, or a combination thereof.

8. The method of claim 7, wherein, in response to the completed execution of the pending refresh operations, the method further comprising:
initiating, by the memory controller of the memory device, a second execution of the PIM operation on the first plurality of memory banks of the memory device; and
initiating, by the memory controller of the memory device, a second execution of the refresh operation on the second plurality of memory bank after the second execution of the PIM operation completes.

9. An apparatus, comprising:
one or more memories storing processor-executable code; and
one or more processors coupled with the one or more memories and individually or collectively operable to execute the code to cause the apparatus to:
initiate, by a memory controller of a memory device, execution of a PIM operation on a first plurality of memory banks of the memory device;
select, by the memory controller of the memory device, a second plurality of memory banks of the memory device different than the first plurality of memory banks to execute a refresh operation based at least in part on knowledge of the initiating the execution of the PIM operation on the first plurality of memory banks;
initiate, by the memory controller of the memory device, execution of the refresh operation on the second plurality of memory banks; and
switch, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

10. The apparatus of claim 9, wherein the one or more processors are individually or collectively further operable to execute the code to cause the apparatus to:
disable execution of the refresh operation on the first plurality of memory banks while the first plurality of memory banks execute the PIM operation.

11. The apparatus of claim 9, wherein each of the first plurality of memory banks and each of the second plurality of memory banks are associated with a single respective processing unit.

12. The apparatus of claim 9, wherein each of the first plurality of memory banks and the second plurality of memory banks comprises eight banks.

13. The apparatus of claim 9, wherein to select the second plurality of memory banks for the refresh operation is performed on a per-bank basis.

14. The apparatus of claim 9, wherein the one or more processors are individually or collectively further operable to execute the code to cause the apparatus to:
increment a counter corresponding to pending refresh operations while the first plurality of memory banks executes the PIM operation and the second plurality of memory banks executes the refresh operation.

15. The apparatus of claim 14, wherein, in response to the counter incrementing up to a postponement threshold and the PIM operation completing execution, the one or more processors are individually or collectively further operable to execute the code to cause the apparatus to:
initiate, by the memory controller, execution of the pending refresh operations on one or more memory banks of the first plurality of memory banks, the second plurality of memory banks, or a combination thereof.

16. The apparatus of claim 15, wherein, in response to the completed execution of the pending refresh operations, the one or more processors are individually or collectively further operable to execute the code to cause the apparatus to:
initiate, by the memory controller of the memory device, a second execution of the PIM operation on the first plurality of memory banks of the memory device; and
initiate, by the memory controller of the memory device, a second execution of the refresh operation on the second plurality of memory bank after the second execution of the PIM operation completes.

17. A non-transitory computer-readable medium storing code for wireless communications, the code comprising instructions executable by one or more processors to:
initiate, by a memory controller of a memory device, execution of a PIM operation on a first plurality of memory banks of the memory device;
select, by the memory controller of the memory device, a second plurality of memory banks of the memory device different than the first plurality of memory banks to execute a refresh operation based at least in part on knowledge of the initiating the execution of the PIM operation on the first plurality of memory banks;
initiate, by the memory controller of the memory device, execution of the refresh operation on the second plurality of memory banks; and
switch, in response to completing execution of the PIM operation on the first plurality of memory banks and by the memory controller of the memory device, execution of the refresh operation on the second plurality of memory banks to the first plurality of memory banks and execution of the PIM operation on the first plurality of memory banks to the second plurality of memory banks.

18. The non-transitory computer-readable medium of claim 17, the code further comprising instructions executable by one or more processors to:
disable execution of the refresh operation on the first plurality of memory banks while the first plurality of memory banks execute the PIM operation.

19. The non-transitory computer-readable medium of claim 17, wherein each of the first plurality of memory banks and each of the second plurality of memory banks are associated with a single respective processing unit.

20. The non-transitory computer-readable medium of claim 17, wherein each of the first plurality of memory banks and the second plurality of memory banks comprises eight banks.
